(19) United States
(12) Patent Application Publication
(10) Pub. No.: US 2015/0061698 A1
(43) Pub. Date: Mar. 5, 2015

(54) ELECTROMAGNETIC INTERFERENCE (EMI) TEST APPARATUS

(71) Applicant: DELPHI TECHNOLOGIES, INC., TROY, MI (US)

(72) Inventors: VINEESH S., KASARAGOD (IN); BRIAN W. JOHNSON, KOKOMO, IN (US); ASHOK KUMAR VIJAYARAJ, BANGALORE (IN)

(73) Assignee: DELPHI TECHNOLOGIES, INC., TROY, MI (US)

(21) Appl. No.: 14/085,061

(22) Filed: Nov. 20, 2013

(30) Foreign Application Priority Data
Sep. 5, 2013 (IN) 3992/CHE/2013

(51) Int. Cl. G01R 31/00

(52) U.S. Cl. CPC G01R 31/002
USPC 324/612

(57) ABSTRACT

A radio-frequency (RF) energy coupling apparatus for electromagnetic interference (EMI) susceptibility testing of a device. The apparatus includes a ground-plane, a micro-strip, a first dielectric layer, a coupling-strip, and a second dielectric layer. The micro-strip overlies the ground-plane. The first dielectric layer is interposed between the ground-plane and the micro-strip. The combination of the ground-plane, the micro-strip, and the first dielectric layer cooperate to form a micro-strip transmission line configured to propagate RF energy from a RF generator to a termination load. The coupling-strip overlies the micro-strip opposite the first dielectric layer. The coupling-strip is configured to couple RF energy from the micro-strip to a harness wire connected to the device. The second dielectric layer is interposed between the coupling-strip and the micro-strip.

### TECHNICAL FIELD OF INVENTION

This disclosure generally relates to a radio-frequency (RF) energy coupling apparatus for electromagnetic interference (EMI) susceptibility testing of a device, and more particularly relates to using a micro-strip transmission line to couple RF energy into a wire connected to a device under test.

### BACKGROUND OF INVENTION

Electrical devices sold to vehicle manufactures are typically required to comply with the Electromagnetic Interference (EMI) or Electromagnetic Compatibility (EMC) specifications established by the vehicle manufactures. One test used to determine compliance with the vehicle manufacture's specification is the so-called Bulk Current Injection (BCI) test. During BCI testing, bundles of wires are encompassed by a current injection probe that is clamped around the wires. A relatively high power (up to 50 Watts) radio frequency (RF) signal is supplied to the current injection probe to inductively couple RF currents into the wires encompassed by the current injection probe. Because of the expense of generating the high power RF signal, and the expense of providing a RF screen room for the BCI test, the BCI test may not be readily available for use by engineers when automotive products are being developed. What is needed is a less expensive test method that can be used by engineers while developing new products, or while seeking to determine why a product did not pass a BCI test.

### SUMMARY OF THE INVENTION

In accordance with one embodiment, a radio-frequency (RF) energy coupling apparatus for electromagnetic interference (EMI) susceptibility testing of a device is provided. The apparatus includes a ground-plane, a micro-strip, a first dielectric layer, a coupling-strip, and a second dielectric layer. The micro-strip overlies the ground-plane. The first dielectric layer is interposed between the ground-plane and the micro-strip. The combination of the ground-plane, the micro-strip, and the first dielectric layer cooperate to form a micro-strip transmission line configured to propagate RF energy from a RF generator to a termination load. The coupling-strip overlies the micro-strip opposite the first dielectric layer. The coupling-strip is configured to couple RF energy from the micro-strip to a harness wire connected to the device. The second dielectric layer is interposed between the coupling-strip and the micro-strip.

Further features and advantages will appear more clearly on a reading of the following detailed description of the preferred embodiment, which is given by way of non-limiting example only and with reference to the accompanying drawings.

### BRIEF DESCRIPTION OF DRAWINGS

The present invention will now be described, by way of example with reference to the accompanying drawings, in which:

FIG. 1 is a schematic of a test system using a radio-frequency (RF) energy coupling apparatus in accordance with one embodiment;

FIGS. 2A and 2B are top and end views, respectively, of a micro-strip transmission line that is part of the radio-frequency (RF) energy coupling apparatus of FIG. 1 in accordance with one embodiment;

FIGS. 3A and 3B are bottom and inverted-end views, respectively, of a coupling assembly that is part of the radio-frequency (RF) energy coupling apparatus of FIG. 1 in accordance with one embodiment; and

FIGS. 4A and 4B are top and end views, respectively, of the radio-frequency (RF) energy coupling apparatus of FIG. 1 including RF connectors in accordance with one embodiment.

### DETAILED DESCRIPTION

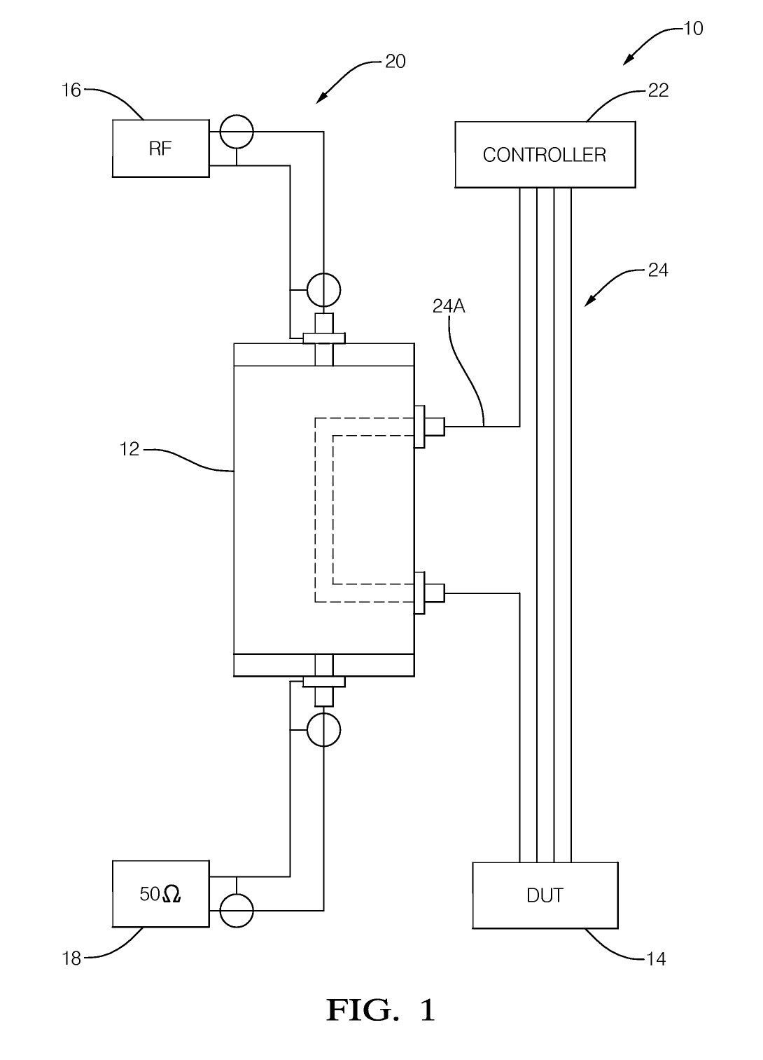

FIG. 1 illustrates a non-limiting example of a test system 10 that includes a radio-frequency (RF) energy coupling apparatus, hereafter referred to as the apparatus 12, for electromagnetic interference (EMI) susceptibility testing of a device 14. The device 14 is labeled in FIG. 1 as DUT to mean ‘device under test’. As described above, the known bulk current injection (BCI) test method is a relatively expensive test to perform as a high power radio frequency (RF) amplifier, a complicated current injection probe, and a RF screen room are needed to perform a BCI test. The test system 10 presented herein is a relatively low cost tool that can be used by engineers to, for example, pre-test the device 14 prior to submitting the device for BCI testing, or as an investigation tool when seeking to understand why the device 14 did not pass a BCI test. It is also recognized that the test system 10 may be used independent of BCI testing as part of a product development activity.

In general, the test system 10 includes an RF generator 16 configured to output RF signals at various frequencies and amplitudes. In contrast to the BCI test which may require up to fifty watts (50 W) of power to induce the desired current into a wiring harness connected to the device under test, the RF generator 16 only needs to output about one-hundred milli-Watts (100 mW or 0.1 W) to be effective to evaluate the device 14. The test system 10 may also include a termination load 18, for example a fifty Ohm (50Ω) load, to provide a proper termination of an RF signal 20 emitted by the RF generator 16 and propagating through the apparatus 12.

The test system 10 may also include a controller 22, such as an electronic control module (ECM), configured to operate the device 14 and provide a representative termination load of a wiring harness 24 that corresponds to whatever the device 14 is connected to during normal in-vehicle operation. Alternatively, the controller 22 may be a custom built device that merely mimics the input/output characteristics of whatever the device 14 is connected to during normal in-vehicle operation. In practice, each of the wires that form the wiring harness 24 may include connectors (not shown) installed in the wiring harness 24 so that each wire can be individually opened and connected to the apparatus 12. Once connected, RF energy from the RF signal 20 can be coupled into each wire of the wiring harness 24 by the apparatus 12, and thereby injected into the device 14 for testing the immunity or susceptibility of the device 14 to RF interference (RFI) or electromagnetic interference (EMI).

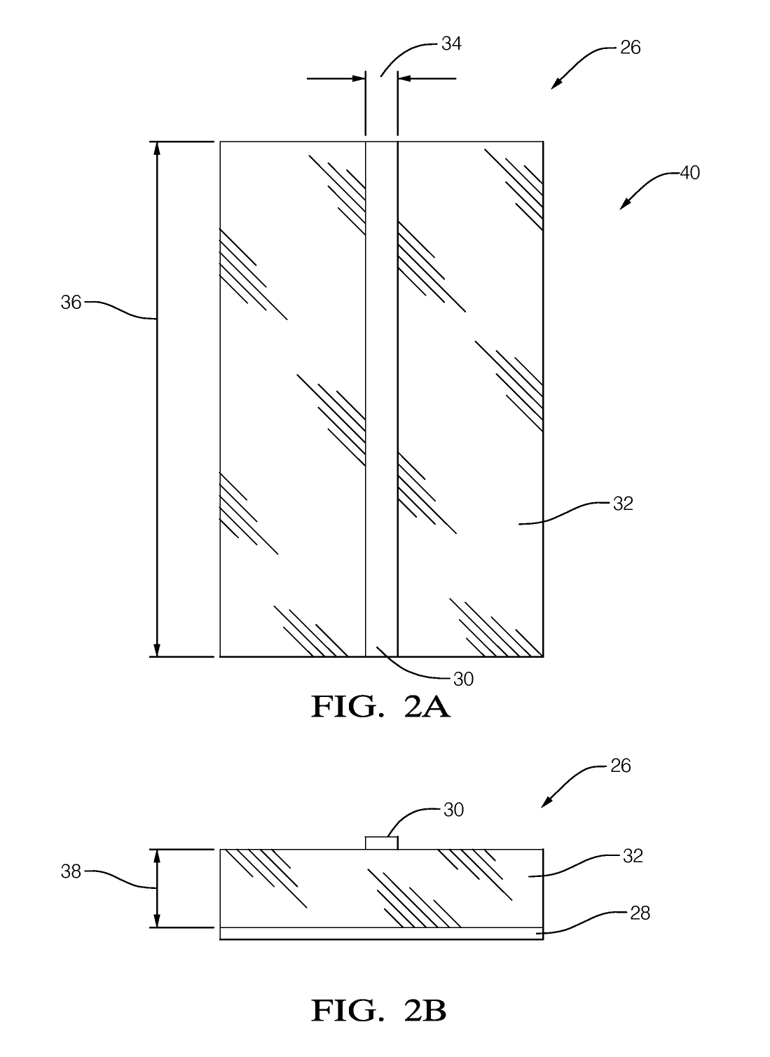

FIGS. 2A and 2B illustrate, respectively, a non-limiting example of a top view and end view of a lower portion 26 of the apparatus 12 that includes a ground-plane 28; a micro-strip 30 overlying the ground-plane 28; and a first dielectric layer 32 interposed between the ground-plane 28 and the micro-strip 30. By way of example and not limitation, the micro-strip 30 may have a strip-width 34 of three millimeters (3 mm) and a strip-length 36 of one-hundred-ten millimeters (110 mm). The ground-plane 28 may have a plane-length equal to the strip-length 36, and a plane-width of sixty millimeters (60 mm). The first dielectric layer 32 may have the same length and width dimensions as the ground-plane 28, and preferably has a substrate-thickness 38 of one-point-six millimeters (1.6 mm).

Preferably, the first dielectric layer 32 is formed of circuit board material such as the readily available FR-4 material. Similarly, the micro-strip 30 and the ground-plane 28 are preferably formed of copper foil so that the lower portion 26 can be fabricated using conventional printed circuit board manufacturing techniques. The copper foil may be seven-hundred-ten micrometers (710 um) thick, which is commonly called two-ounce copper in circuit board manufacturing circles. However, it is recognized that other thickness of copper may be suitable.

Those skilled in the RF transmission arts will recognize that the combination of the ground-plane 28, the micro-strip 30, and the first dielectric layer 32 in the example dimensions suggested cooperate to form a micro-strip transmission line 40 configured to propagate RF energy from the RF generator 16 to the termination load 18. Using a relative permittivity of four-point-three (4.3) for the first dielectric layer 32, the characteristic impedance of the micro-strip transmission line 40 is calculated to be about fifty Ohms (50Ω). Accordingly, as suggested above, the impedance of the termination load 18 is selected to match the characteristic impedance of the micro-strip transmission line 40. It is recognized that other combinations of dimensions and materials could be used to achieve a characteristic impedance of 50Ω. The example dimensions and materials presented herein were used to build a prototype of the apparatus 12 for evaluation in the test system 10.

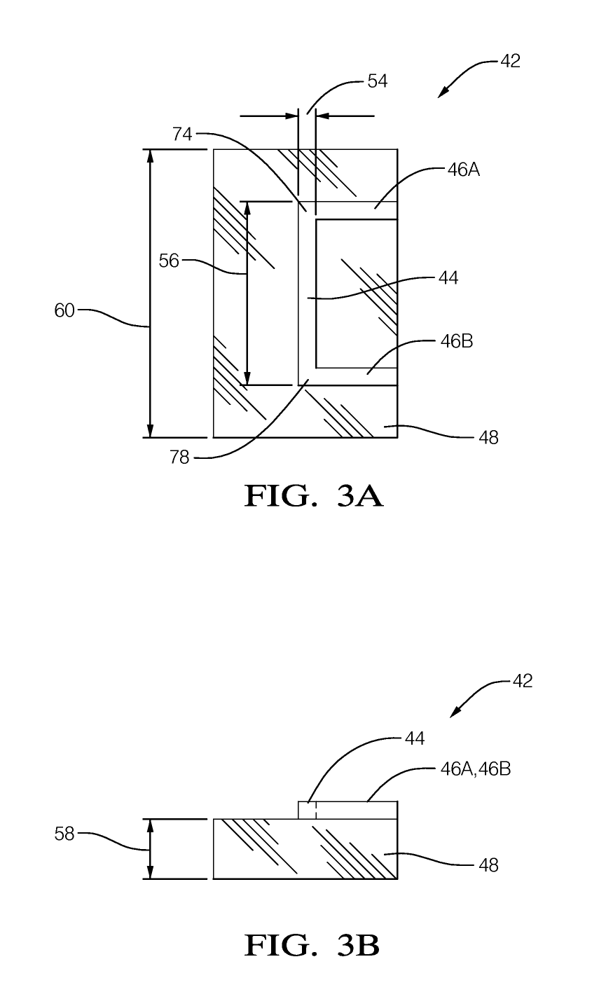

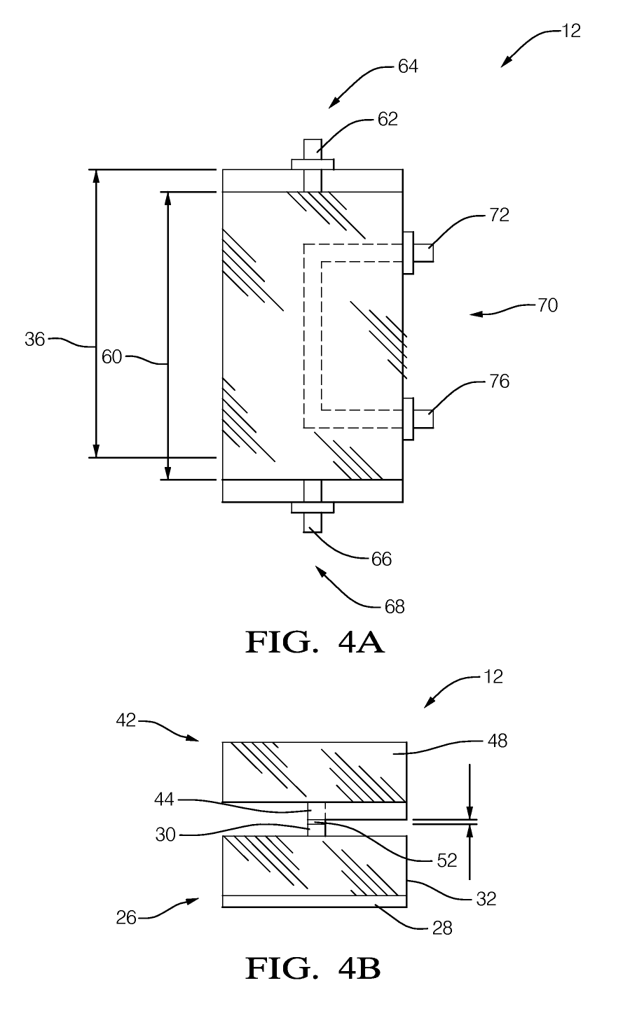

FIGS. 3A and 3B illustrate, respectively, a non-limiting example of a bottom view and inverted end view (inverted relative to FIG. 4B) of an upper portion 42 of the apparatus 12 that includes a coupling-strip 44. As shown in FIG. 4, when the apparatus 12 is assembled, the lower portion 26 and the upper portion 42 are arranged so the micro-strip 30 and the coupling-strip 44 are as close together as possible, but isolated electrically by a second dielectric layer 52 (FIG. 4B), the reasons for which will become clear in the further description of the apparatus 12 provided below. In other words, the coupling-strip 44 is configured to overlie the micro-strip 30 opposite the first dielectric layer 32. The upper portion 42 may also include feed-strips 46A and 46B to provide an electrical connection from the coupling strip 44 to the edge of a third dielectric layer 48 for making an electrical connection to the wiring harness 24. By locating the coupling-strip 44 close to the micro-strip 30, the coupling-strip 44 is configured to readily couple RF energy from the micro-strip 30 to a wire 24A of the wiring harness connected to the device.

Preferably, the coupling-strip 44 has a coupling-width 54 substantially equal to a strip-width 34 of the micro-strip 30, 3 mm for example. Having the coupling-width 54 substantially equal to the strip-width 34 is preferred as doing so maximizes the RF energy coupling between the coupling-strip 44 and the micro-strip 30. The coupling-strip 44 also has a coupling-length 56 of seventy millimeters (70 mm) that is the length of the coupling-strip that overlies the 110 mm length of the micro-strip 30. The coupling-length 56 affects the efficiency of RF energy coupling, and can be selected to avoid resonance effects. While not subscribing to any particular theory, the coupling length 56 should be greater than one-tenth of a wavelength (λ/10) of the lowest frequency of the RF signal 20.

The second dielectric layer 52 is generally interposed between the coupling-strip 44 and the micro-strip 30 for direct-current (DC) electrical isolation. However it is also desirable to have the second dielectric layer 52 as thin as possible so that the RF energy coupling between the coupling-strip 44 and the micro-strip 30 is maximized. The prototype tested used a fifty micrometer (50 um) thick layer of stationary cello-tape commonly used for, among other things, securing decorative wrapping paper about a wrapped gift. It is recognize that a wide variety of materials may be suitable for use as the second dielectric layer 52, and the selection used for the prototype was only selected based on convenience. For example, the second dielectric layer 52 may be formed by the protective coating commonly placed over circuit traces on a printed circuit board to protect the metal used to form the circuit traces.

The upper portion 42 of the apparatus 12 illustrated in this non-limiting example includes the third dielectric layer 48 overlying the coupling-strip 44 opposite the second dielectric layer 52. Preferably the third dielectric layer 48 is as thin as possible in order to minimize the effect the third dielectric layer 48 has on the characteristic impedance of the micro-strip transmission line 40. The prototype of the apparatus 12 that was tested had a third dielectric layer 48 with a second substrate-thickness of eight-hundred-micrometers (800 um or 0.8 mm). However, the third dielectric layer 48 was only included to make it convenient to build a prototype. Preferably, an assembly technique is used that allows for the coupling-strip 44 to overlie the micro-strip 30 without having to rely on the third dielectric layer 48 to support the coupling-strip 44. As such, the micro-strip transmission line 40 is characterized as having a characteristic impedance, the third dielectric layer 48 is characterized by a third dielectric thickness 58, and the third dielectric thickness 58 is selected to minimize influence on the characteristic impedance of the micro-strip transmission line 40.

FIGS. 4A and 4B illustrate, respectively, a non-limiting example of a top view and end view of the apparatus 12 that includes a first connector 62 coupled electrically to the ground-plane 28 and the micro-strip 30 at a first end 64 of the apparatus, and a second connector 66 coupled electrically to the ground-plane 28 and the micro-strip 30 at a second end 68 of the apparatus that is opposite the first end 64. It is noted that the first connector 62 and the second connector 66 are not shown only to simplify the illustration. The first connector 62 and the second connector 66 are preferably co-axial type connectors suitable for the frequency range of the RF signal 20 (FIG. 1). A suitable connector is a Sub-Miniature version A (SMA) type connector available from a number of manufacturers.

It is noted that the third dielectric layer 48 has a substrate-length 60 shorter than the strip-length 36 so there is clearance to attach the first connector 62 and the second connector 66. A suitable clearance for each connector is ten millimeters (10 mm) and so the substrate length of ninety millimeters (90 mm) was used for the prototype of the apparatus 12. The width of the third dielectric layer 48 was selected to match the width of the first dielectric layer 32, sixty millimeters (60 mm) for example, so support between the third dielectric layer 48 and the first dielectric layer 32 could be added if necessary to make the apparatus 12 robust.

The apparatus 12 may also include a third connector 72 coupled electrically to an input end 74 of the coupling-strip 44 via the feed strip 46A; and a fourth connector 76 coupled electrically to an output end 78 the coupling-strip 44 via the feed strip 46B. The third connector 72 and the fourth connector 76 are both preferably arranged along a first side 70 of the apparatus 12 adjacent the first end 64 and the second end 66 so the test system 10 can be neatly arranged as suggested in FIG. 1.

Accordingly, a test system 10, a radio-frequency (RF) energy coupling apparatus (the apparatus 12) for electromagnetic interference (EMI) susceptibility testing of a device 14 is provided. The apparatus 12 provides for efficient coupling of RF energy into a wire 24A of a wiring harness 24 connected to a device 14 that is being tested for EMI susceptibility. Due to efficient coupling of RF energy, a much lower power amplifier can be used to regenerate the RF signal 20 and no screen room facility is needed. The apparatus 12 has been demonstrated to be handy to easily debug BCI test failures in the device 14. The coupling has been shown to be efficient for different configurations of the controller 22. The prototype of the apparatus built to the dimensions described herein has a flat band response for frequencies from 50 MHz-1000 MHz. The test system 10 is able to replicate a BCI test anomaly without comprehensive EMC test facilities.

While this invention has been described in terms of the preferred embodiments thereof, it is not intended to be so limited, but rather only to the extent set forth in the claims that follow.

We claim:

1. A radio-frequency (RF) energy coupling apparatus for electromagnetic interference (EMI) susceptibility testing of a device, said apparatus comprising:
a ground-plane;
a micro-strip overlying the ground-plane;
a first dielectric layer interposed between the ground-plane and the micro-strip, wherein the combination of the ground-plane, the micro-strip, and the first dielectric layer cooperate to form a micro-strip transmission line configured to propagate RF energy from a RF generator to a termination load;
a coupling-strip overlying the micro-strip opposite the first dielectric layer, wherein the coupling-strip is configured to couple RF energy from the micro-strip to a harness wire connected to the device; and
a second dielectric layer interposed between the coupling-strip and the micro-strip.

2. The apparatus in accordance with claim 1, wherein the coupling-strip has a coupling-width substantially equal to a strip-width of the micro-strip.

3. The apparatus in accordance with claim 1, wherein the second dielectric layer is characterized by a second dielectric thickness, wherein the second dielectric thickness is selected to maximize coupling of RF energy from the micro-strip to the coupling-strip.

4. The apparatus in accordance with claim 1, wherein the apparatus includes a third dielectric layer overlying the coupling-strip opposite the second dielectric layer.

5. The apparatus in accordance with claim 4, wherein the micro-strip transmission line is characterized as having a characteristic impedance, the third dielectric layer is characterized by a third dielectric thickness, and the third dielectric thickness is selected to minimize influence on the characteristic impedance of the micro-strip transmission line.

6. The apparatus in accordance with claim 1, wherein the apparatus includes a first connector coupled electrically to the ground-plane and the micro-strip at a first end of the apparatus, and a second connector coupled electrically to the ground-plane and the micro-strip at a second end of the apparatus that is opposite the first end.

7. The apparatus in accordance with claim 6, wherein the apparatus includes a third connector coupled electrically to an input end of the coupling-strip and a fourth connector coupled electrically to an output end the coupling-strip.

8. The apparatus in accordance with claim 7, wherein the third connector and the fourth connector are arranged along a first side of the apparatus adjacent the first end and the second end.
